(19) United States
(12) Patent Application Publication
(10) Pub. No.: US 2026/0150723 A1
(43) Pub. Date: May 28, 2026

(54) SEMICONDUCTOR PACKAGE

(71) Applicant: Samsung Electronics Co., Ltd., Suwon-si (KR)

(72) Inventor: Bojeong PARK, Suwon-si (KR)

(21) Appl. No.: 19/217,217

(22) Filed: May 23, 2025

(30) Foreign Application Priority Data
Nov. 22, 2024 (KR) 10-2024-0168771

(51) Int. Cl. H01L 23/00; H01L 23/31; H01L 23/49; H01L 23/538; H01L 25/04

(52) U.S. Cl. CPC H10W 70/611; H10W 70/65; H10W 72/50; H10W 74/121; H10W 90/00; H10W 72/07255; H10W 72/251; H10W 72/823; H10W 74/117; H10W 90/754

(57) ABSTRACT

A semiconductor package according to some embodiments includes a first semiconductor chip including a first pad, a second semiconductor chip including a second pad, a package substrate including a substrate pad, a filling layer between the first semiconductor chip and the second semiconductor chip, a first ball connected to the first pad, a second ball connected to the second pad, and a wire connected to the second ball and the substrate pad. The filling layer surrounds at least a portion of the first ball and the second ball. The first ball overlaps the second ball and is spaced apart from the wire and the second ball.

### CROSS-REFERENCE TO RELATED APPLICATION

This U.S. non-provisional patent application claims priority under 35 U.S.C. § 119 of Korean Patent Application No. 10-2024-0168771, filed on Nov. 22, 2024, the entire contents of which are hereby incorporated by reference.

### FIELD

The present invention relates to semiconductor packages, and more particularly, to semiconductor packages including a filling layer.

### BACKGROUND

An integrated circuit chip is packaged into a semiconductor package to have a suitable form to be installed in an electronic device. In general, in a semiconductor package, a semiconductor chip is mounted on a printed circuit board, and the semiconductor chip and the printed circuit board are electrically connected to each other using bonding wires or bumps. With the development of electronics industry, various research projects are being carried out to improve the reliability of semiconductor packages.

### SUMMARY

The present disclosure defines semiconductor packages with improved electrical characteristics and reliability and methods for manufacturing the same.

Some embodiments of the inventive concept define a semiconductor package including: a first semiconductor chip including a first pad; a second semiconductor chip including a second pad; a package substrate including a substrate pad; a filling layer between the first semiconductor chip and the second semiconductor chip; a first ball connected to the first pad; a second ball connected to the second pad; and a wire connected to the second ball and the substrate pad, wherein the filling layer surrounds at least a portion of the first ball and the second ball, and wherein the first ball overlaps the second ball and is spaced apart from the wire and the second ball.

In some embodiments of the inventive concept, a semiconductor package includes: a first semiconductor chip including a first pad; a second semiconductor chip including a second pad; a package substrate including a substrate pad; a filling layer between the first semiconductor chip and the second semiconductor chip; a first ball connected to the first pad; a second ball connected to the second pad; and a first wire connected to the second ball and the substrate pad, wherein the filling layer includes a base part surrounding at least a portion of the first ball and the second ball and an interposed part between the first ball and the second ball.

In some embodiments of the inventive concept, a semiconductor package includes: a first semiconductor chip; a second semiconductor chip overlapping the first semiconductor chip; a package substrate including a substrate pad; a first ball connected to the first semiconductor chip; a second ball connected to the second semiconductor chip and spaced apart from the first ball; a wire connected to the second ball and the substrate pad and spaced apart from the first ball; a filling layer between the first semiconductor chip and the second semiconductor chip and surrounding at least a portion of the first ball and the second ball; an adhesive layer between the second semiconductor chip and the package substrate; and a molding layer surrounding at least a portion of the first semiconductor chip, the second semiconductor chip, and the wire, wherein the first semiconductor chip includes: a first pad connected to the first ball; a first substrate; a first semiconductor device on a lower surface of the first substrate; a first insulating structure surrounding at least a portion of the first semiconductor device; and first conductive structures in the first insulating structure and electrically connecting the first semiconductor device and the first pad, wherein the second semiconductor chip includes: a second pad connected to the second ball; a second substrate; a second semiconductor device on an upper surface of the second substrate; a second insulating structure surrounding at least a portion of the second semiconductor device; and second conductive structures in the second insulating structure and electrically connecting the second semiconductor device and the second pad, and wherein the filling layer electrically connects the first ball and the wire.

### BRIEF DESCRIPTION

The accompanying drawings are included to provide a further understanding of the inventive concept and are incorporated in and constitute a part of this specification. The drawings illustrate some embodiments of the inventive concept and, together with the description, serve to explain principles of the inventive concept. In the drawings:

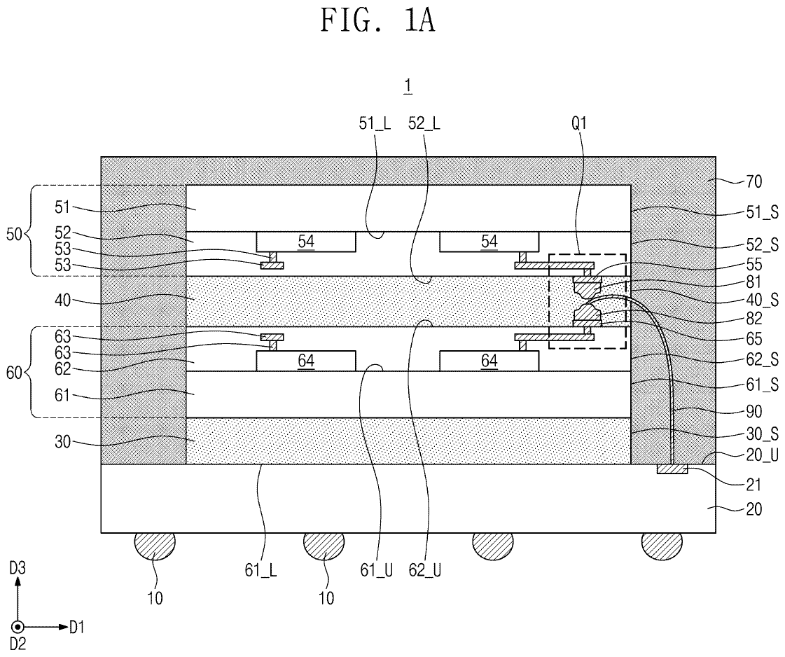

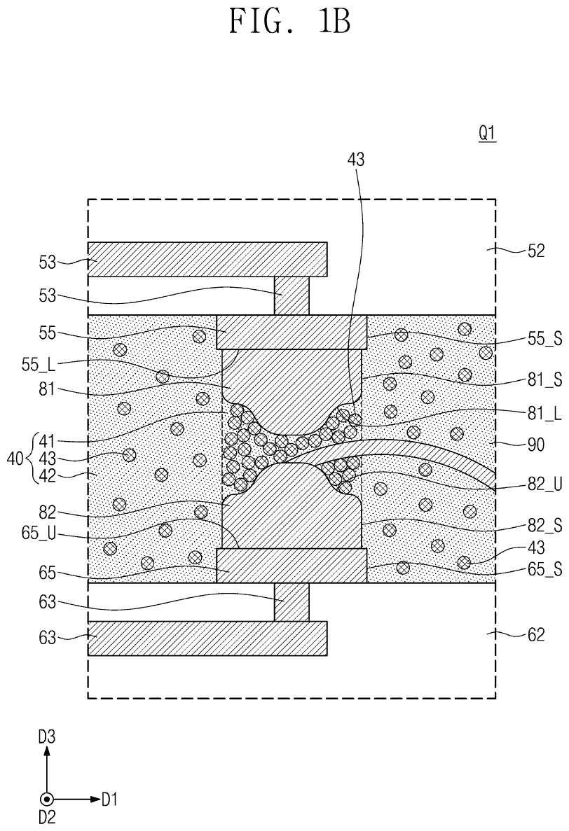

FIG. 1A is a cross-sectional view of a semiconductor package according to some embodiments;

FIG. 1B is an enlarged view of region Q1 of FIG. 1A;

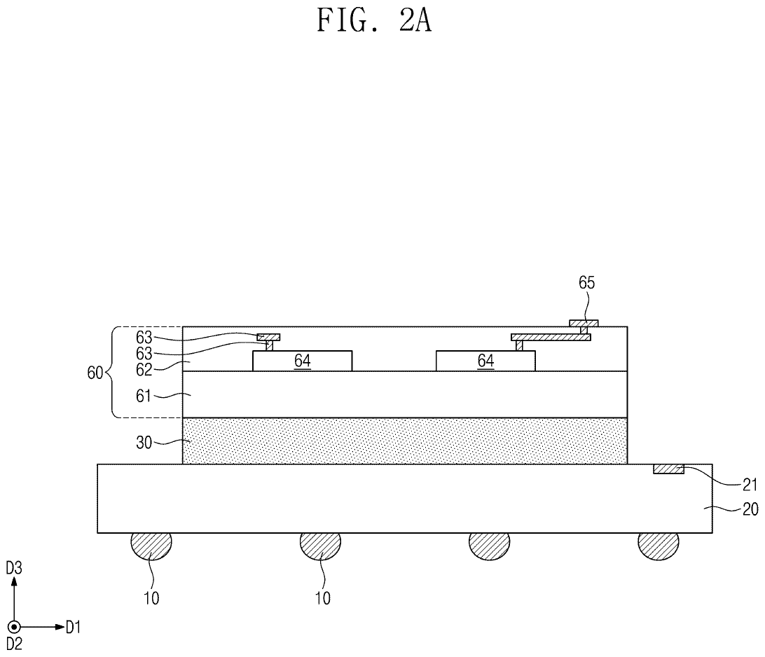

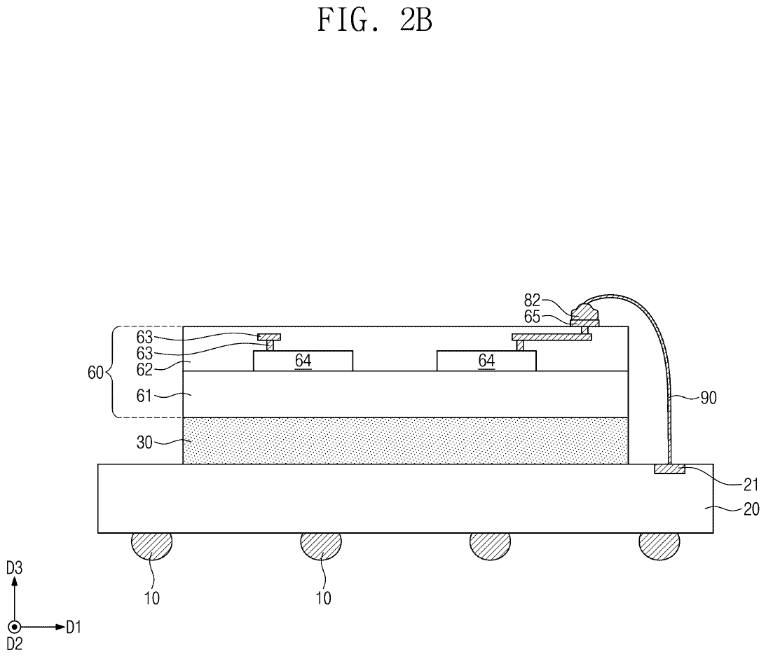

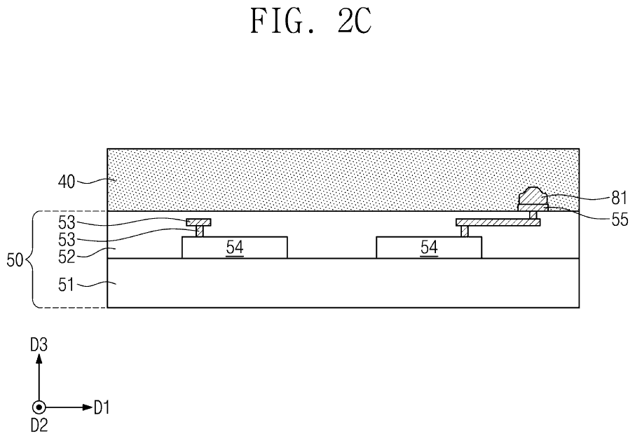

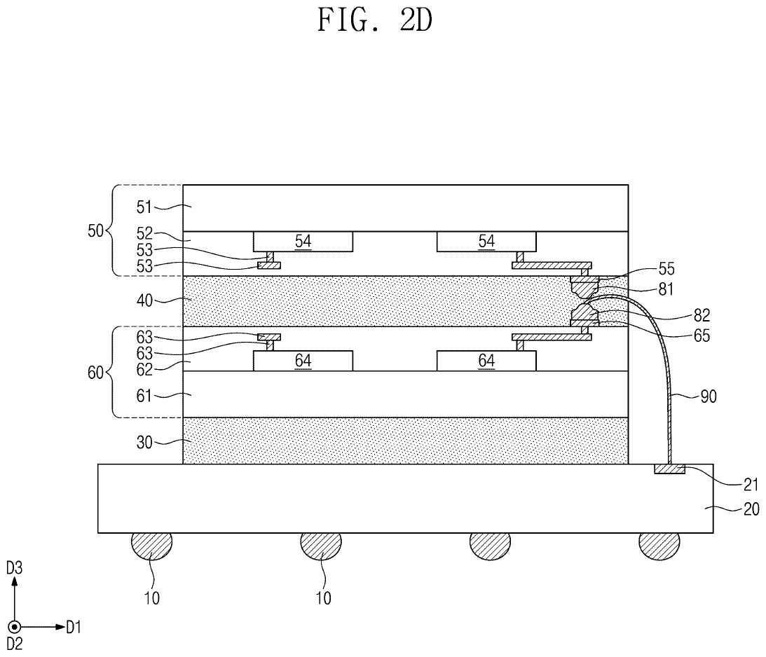

FIGS. 2A, 2B, 2C, and 2D are cross-sectional views for describing a method for manufacturing a semiconductor package according to some embodiments;

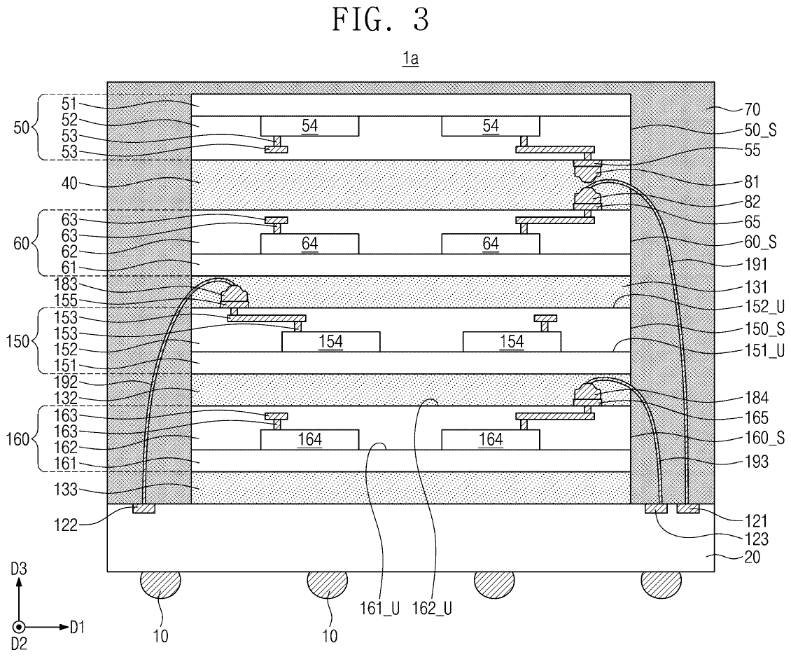

FIG. 3 is a cross-sectional view of a semiconductor package according to some embodiments;

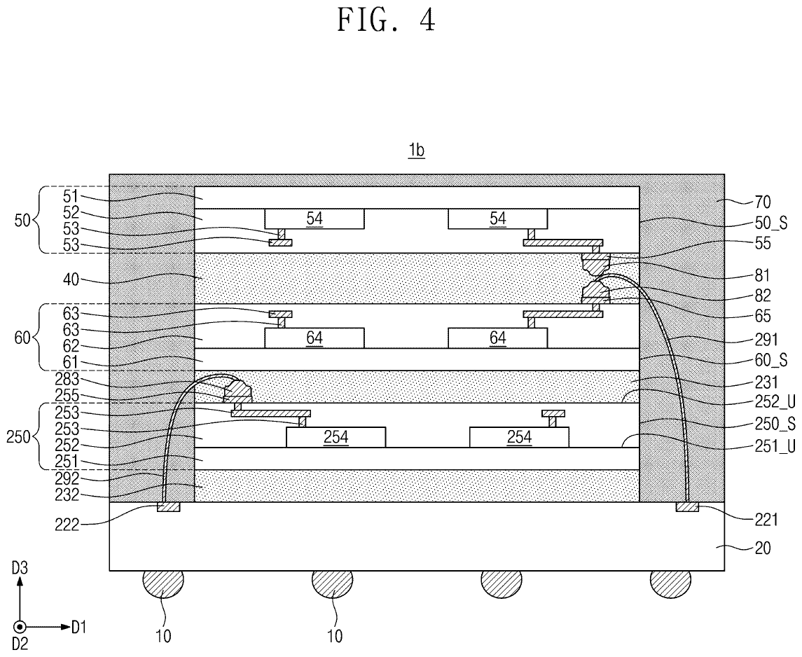

FIG. 4 is a cross-sectional view of a semiconductor package according to some embodiments;

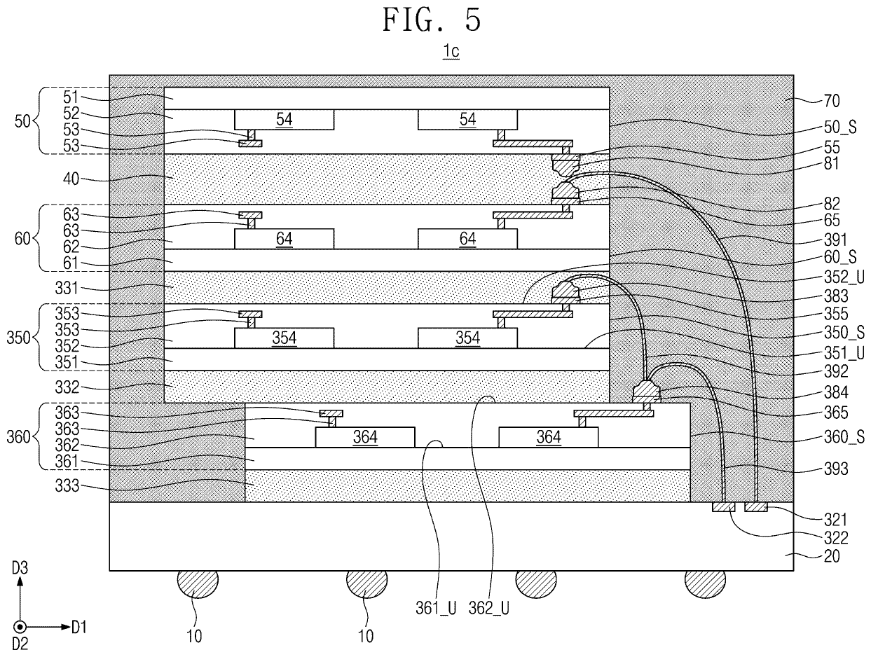

FIG. 5 is a cross-sectional view of a semiconductor package according to some embodiments;

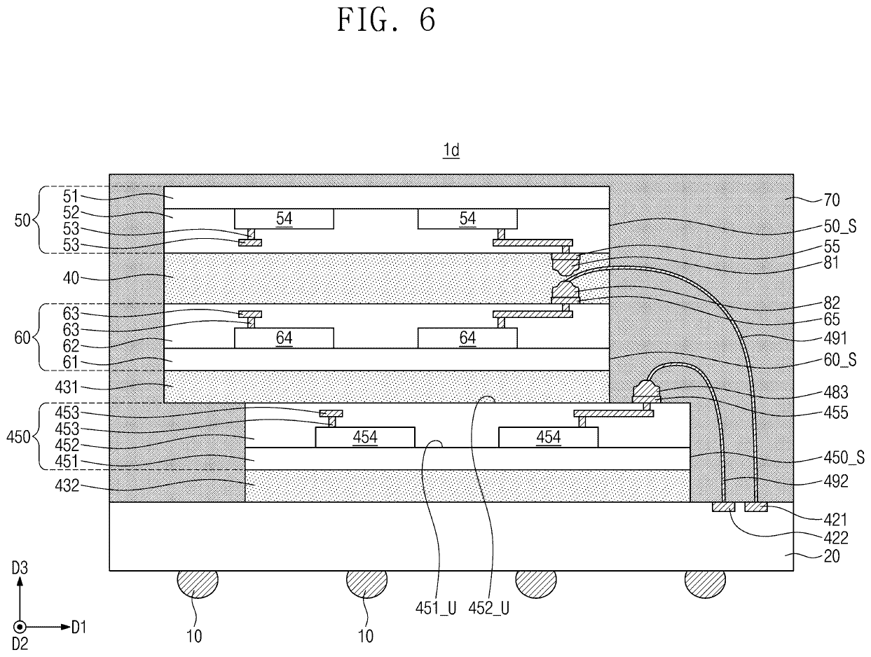

FIG. 6 is a cross-sectional view of a semiconductor package according to some embodiments;

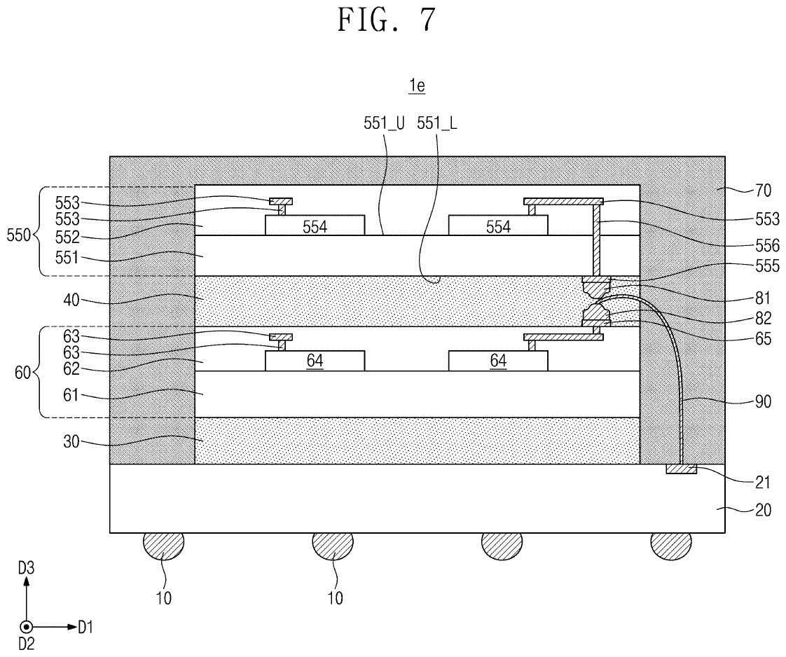

FIG. 7 is a cross-sectional view of a semiconductor package according to some embodiments;

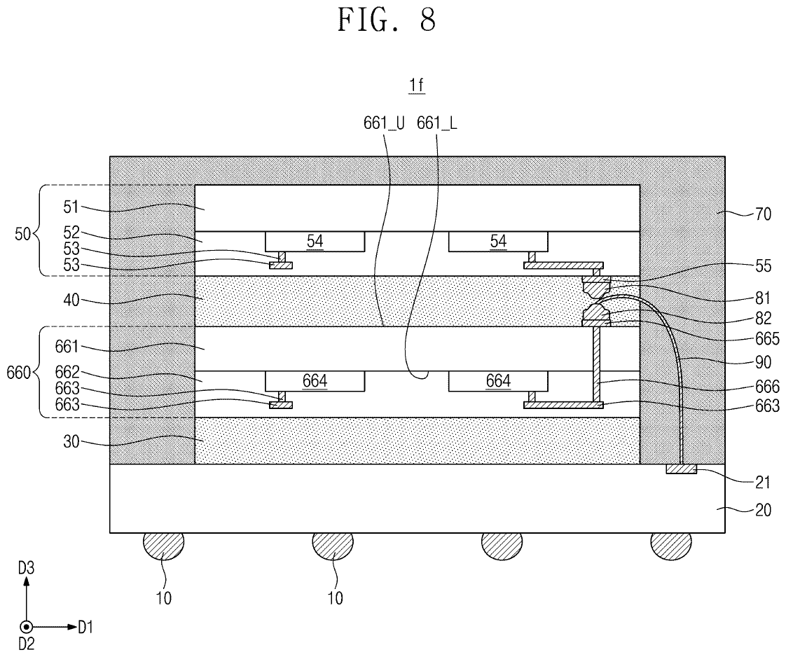

FIG. 8 is a cross-sectional view of a semiconductor package according to some embodiments;

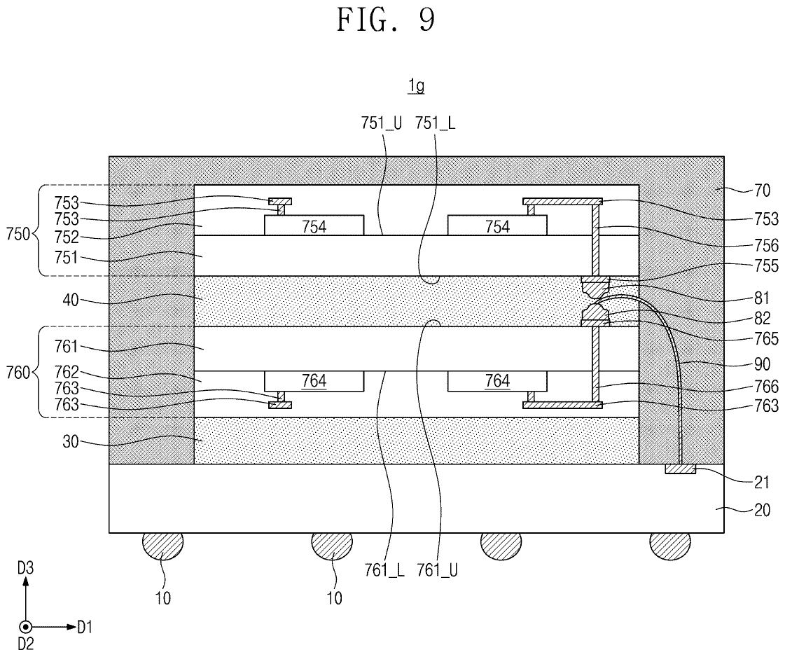

FIG. 9 is a cross-sectional view of a semiconductor package according to some embodiments; and

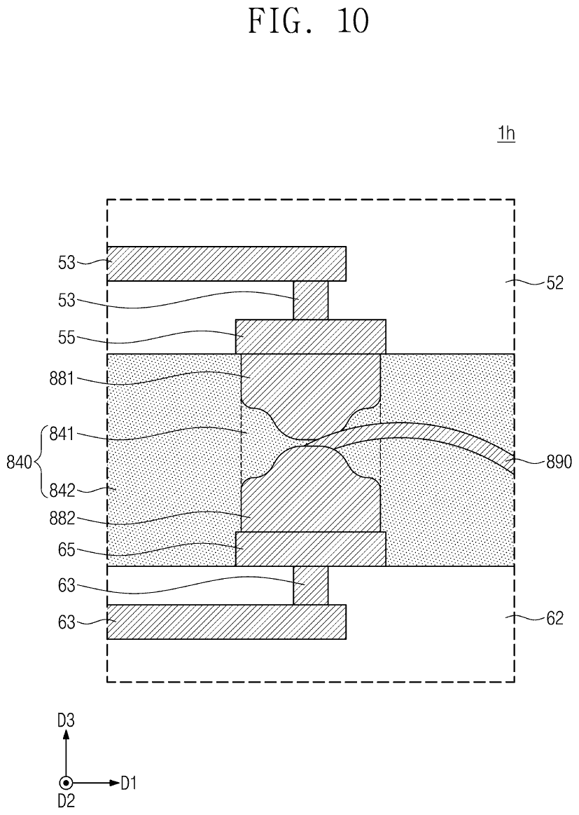

FIG. 10 is an enlarged view of a semiconductor package according to some embodiments.

### DETAILED DESCRIPTION

Hereinafter, a semiconductor package and a method for manufacturing the same according to some embodiments of the inventive concept will be described with reference to the accompanying drawings.

The terms “comprises,” “comprising,” “includes,” and/or “including,” when used herein, specify the presence of stated elements, but do not preclude the presence of additional elements. The term “and/or” includes any and all combinations of one or more of the associated listed items.

The term “connected” may be used herein to refer to a physical and/or electrical connection.

Further, spatially relative terms, such as “under,” “below,” “lower,” “over,” “upper,” etc., may be used herein for ease of description to describe one element or relationship of structures to another element or structure as illustrated in the drawings.

A first element described as “on” a second element may be disposed directly on the second element (e.g., in contact with the second element) or indirectly on the second element (e.g., with an intervening element interposed between the first and second elements). When components or layers are referred to herein as “directly” on, “in contact with,” “contacting,” “engaged with,” “engaging,” or “directly connected,” no intervening components or layers are present. Further, in the specification, the word “on” may include above, beside, and/or below the object portion and does not necessarily mean positioned on the upper side of the object portion based on a gravitational direction.

Components or layers described with reference to “overlap” in a particular direction are at least partially obstructed by one another when viewed along a line extending in the particular direction or in a plane perpendicular to the particular direction. As used herein, “an element A overlapping an element B in a direction C” (or similar language) means that there is at least one line that extends in the direction C that intersects both the element A and the element B. For example, the element B may be a layer that is stacked or superimposed over (i.e., on top of) the element A, in which case the layer B may be described as overlapping the element A in a vertical direction. However, it will be appreciated that the direction C is not limited to the vertical direction and may be, for example, a horizontal direction or any direction between vertical and horizontal.

FIG. 1A is a cross-sectional view of a semiconductor package according to some embodiments. FIG. 1B is an enlarged view of region Q1 of FIG. 1A.

Referring to FIG. 1A, the semiconductor package 1 may include terminals 10, a package substrate 20, an adhesive layer 30, a filling layer 40, a first semiconductor chip 50, a second semiconductor chip 60, a molding layer 70, a first ball 81, a second ball 82, and a wire 90. The first semiconductor chip 50 and the second semiconductor chip 60 are on the package substrate 20.

The package substrate 20 may have a shape of a plate extending along a plane defined by a first direction D1 and a second direction D2. The first direction D1 and the second direction D2 may intersect each other. For example, the first direction D1 and the second direction D2 may be perpendicular to each other.

In some embodiments, the package substrate 20 may be a printed circuit board. In some embodiments, the package substrate 20 may be a redistribution substrate. In some embodiments, the package substrate 20 may be an interposer including a semiconductor substrate.

The terminals 10 may be connected to the package substrate 20. The semiconductor package 1 may be electrically connected to an external device through the terminals 10. The terminals 10 may include a conductive material.

The package substrate 20 may include a substrate pad 21. The substrate pad 21 may be exposed through an upper surface 20_U of the package substrate 20. The substrate pad 21 may include a conductive material.

The adhesive layer 30 may be on the package substrate 20. The second semiconductor chip 60 may be on the adhesive layer 30. The filling layer 40 may be on the second semiconductor chip 60. The first semiconductor chip 50 may be on the filling layer 40.

The first semiconductor chip 50 may include a first substrate 51, a first insulating structure 52, first conductive structures 53, first semiconductor devices 54, and a first pad 55.

The first substrate 51 may be a semiconductor substrate. For example, the first substrate 51 may include silicon, germanium, or silicon-germanium.

The first insulating structure 52 may be on a lower surface 51_L of the first substrate 51. The first insulating structure 52 may be in contact with the lower surface 51_L of the first substrate 51. The first insulating structure 52 may include an insulating material. For example, the first insulating structure 52 may include silicon oxide. In some embodiments, the first insulating structure 52 may be multiple layers including a plurality of insulating layers.

The first semiconductor device 54 may be on the lower surface 51_L of the first substrate 51. The first semiconductor device 54 may be at least partially surrounded by the first insulating structure 52. In some embodiments, the first semiconductor device 54 may be on, or embedded in, the first insulating structure 52. In some embodiments, the first semiconductor device 54 is surrounded or overlapped on at least two sides by the first insulating structure 52. The first semiconductor device 54 may be between the first substrate 51 and the first insulating structure 52. The first semiconductor device 54 may use the lower surface 51_L of the first substrate 51 as an active surface. The first semiconductor device 54 may be, for example, a memory device (e.g., dynamic random access memory (DRAM), static RAM (SRAM), thyristor RAM (TRAM), zero capacitor RAM (ZRAM), twin transistor RAM (TTRAM), flash memory, magnetic RAM (MRAM), spin-transfer torque MRAM (STT-MRAM), ferroelectric RAM (FRAM), phase change RAM (PRAM), resistive RAM (RRAM), polymer RAM, or insulator resistance change memory), a logic device (e.g., a central processing unit (CPU), a graphic processing unit (GPU), or an application processor (AP)), or an image sensor device.

The first pad 55 may be on a lower surface 52_L of the first insulating structure 52. The first pad 55 may be in contact with the lower surface 52_L of the first insulating structure 52. The first insulating structure 52 may be between the first pad 55 and the first substrate 51. The first pad 55 may include a conductive material.

The first conductive structures 53 may be electrically connected to the first semiconductor device 54. At least some of the first conductive structures 53 may electrically connect the first pad 55 and the first semiconductor device 54 The first conductive structures 53 may be in the first insulating structure 52. The first conductive structures 53 may be at least partially surrounded by the first insulating structure 52. In some embodiments, the first conductive structures 53 may be on, or embedded in, the first insulating structure 52. In some embodiments, each of the first conductive structures 53 is surrounded or overlapped on at least two sides by the first insulating structure 52. The first conductive structures 53 may include a conductive material. The first conductive structures 53 may include at least one of a conductive line, conductive contact, conductive via, or conductive pad.

The second semiconductor chip 60 may include a second substrate 61, a second insulating structure 62, second conductive structures 63, second semiconductor devices 64, and a second pad 65.

The second substrate 61 may be a semiconductor substrate. For example, the second substrate 61 may include silicon, germanium, or silicon-germanium.

The second insulating structure 62 may be on an upper surface 61_U of the second substrate 61. The second insulating structure 62 may be in contact with the upper surface 61_U of the second substrate 61. The second insulating structure 62 may include an insulating material. For example, the second insulating structure 62 may include silicon oxide. In some embodiments, the second insulating structure 62 may be multiple layers including a plurality of insulating layers.

The second semiconductor device 64 may be on the upper surface 61_U of the second substrate 61. The second semiconductor device 64 may be at least partially surrounded by the second insulating structure 62. In some embodiments, the second semiconductor device 64 may be on, or embedded in, the second insulating structure 62. In some embodiments, the second semiconductor device 64 is surrounded or overlapped on at least two sides by the second insulating structure 62. The second semiconductor device 64 may be between the second substrate 61 and the second insulating structure 62. The second semiconductor device 64 may use the upper surface 61_U of the second substrate 61 as an active surface. The second semiconductor device 64 may be, for example, a memory device, a logic device, or an image sensor device.

The second pad 65 may be on an upper surface 62_U of the second insulating structure 62. The second pad 65 may be in contact with the upper surface 62_U of the second insulating structure 62. The second insulating structure 62 may be between the second pad 65 and the second substrate 61. The second pad 65 may include a conductive material.

The second conductive structures 63 may be electrically connected to the second semiconductor device 64. At least some of the second conductive structures 63 may electrically connect the second pad 65 and the second semiconductor device 64 The second conductive structures 63 may be in the second insulating structure 62. The second conductive structures 63 may be at least partially surrounded by the second insulating structure 62. In some embodiments, the second conductive structures 63 may be on, or embedded in, the second insulating structure 62. In some embodiments, each of the second conductive structures 63 is surrounded or overlapped on at least two sides by the second insulating structure 62. The second conductive structures 63 may include a conductive material. The second conductive structures 63 may include at least one of a conductive line, conductive contact, conductive via, or conductive pad.

The first semiconductor chip 50 and the second semiconductor chip 60 may overlap each other in the third direction D3. The third direction D3 may intersect the first direction D1 and the second direction D2. For example, the third direction D3 may be a vertical direction perpendicular to the first direction D1 and the second direction D2. The first semiconductor chip 50 and the second semiconductor chip 60 may be spaced apart in the third direction D3.

The first substrate 51 and the second substrate 61 may be spaced apart in the third direction D3. The first insulating structure 52, the second insulating structure 62, the first conductive structures 53, the second conductive structures 63, the first semiconductor devices 54, the second semiconductor devices 64, the first pad 55, and the second pad 65 may be arranged between the first substrate 51 and the second substrate 61.

The first insulating structure 52 and the second insulating structure 62 may be spaced apart in the third direction D3. The first pad 55 and the second pad 65 may be arranged between the first insulating structure 52 and the second insulating structure 62.

The first ball 81 may be connected to the first pad 55. The second ball 82 may be connected to the second pad 65. The first ball 81 and the second ball 82 may be arranged between the first pad 55 and the second pad 65. The first ball 81 and the second ball 82 may include a conductive material.

The adhesive layer 30 may be between the second semiconductor chip 60 and the package substrate 20. The adhesive layer 30 may be in contact with a lower surface 61_L of the second substrate 61 and the upper surface 20_U of the package substrate 20. The adhesive layer 30 may include a polymer material. For example, the adhesive layer 30 may be a die attach film (DAF).

The filling layer 40 may be between the first semiconductor chip 50 and the second semiconductor chip 60. The filling layer 40 may be between the first insulating structure 52 and the second insulating structure 62. The filling layer 40 may be in contact with the lower surface 52_L of the first insulating structure 52 and the upper surface 62_U of the second insulating structure 62. The filling layer 40 may surround at least a portion of each of the first pad 55, the second pad 65, the first ball 81, and the second ball 82. In some embodiments, the first pad 55, the second pad 65, the first ball 81, and/or the second ball 82 may be on, or embedded in, the filling layer 40. In some embodiments, the first pad 55, the second pad 65, the first ball 81, and/or the second ball 82 may each be surrounded or overlapped on at least two sides by the filling layer 40.

The filling layer 40 may include a material different from that of the adhesive layer 30. The filling layer 40 may include a material in which a conductive path may be formed by applied voltage. For example, the filling layer 40 may include an anisotropic conductive film (ACF).

The adhesive layer 30, the filling layer 40, the first semiconductor chip 50, and the second semiconductor chip 60 may overlap each other in the third direction D3. A sidewall 30_S of the adhesive layer 30, a sidewall 40_S of the filling layer 40, a sidewall 51_S of the first substrate 51, a sidewall 52_S of the first insulating structure 52, a sidewall 61_S of the second substrate 61, and a sidewall 62_S of the second insulating structure 62 may be coplanar. The sidewall 30_S of the adhesive layer 30, the sidewall 40_S of the filling layer 40, the sidewall 51_S of the first substrate 51, the sidewall 52_S of the first insulating structure 52, the sidewall 61_S of the second substrate 61, and the sidewall 62_S of the second insulating structure 62 may overlap each other in the third direction D3.

The wire 90 may be connected to the second ball 82 and the substrate pad 21. The wire 90 may electrically connect the second ball 82 and the substrate pad 21. The wire 90 may be in contact with the second ball 82 and the substrate pad 21. The wire 90 may include a conductive material.

In some embodiments, the wire 90 may include the same material as the second ball 82, and the wire 90 and the second ball 82 may be seamlessly connected to each other and form an integrated structure. In some embodiments, the wire 90 and the second ball 82 may be formed through a ball bonding process.

The molding layer 70 may surround at least a portion of each of the adhesive layer 30, the filling layer 40, the first semiconductor chip 50, the second semiconductor chip 60, and the wire 90. In some embodiments, the adhesive layer 30, the filling layer 40, the first semiconductor chip 50, the second semiconductor chip 60, and the wire 90 may be on, or embedded in, the molding layer 70. In some embodiments, the adhesive layer 30, the filling layer 40, the first semiconductor chip 50, the second semiconductor chip 60, and the wire 90 may each be surrounded or overlapped on at least two sides by the molding layer 70. The molding layer 70 may include a polymer material, for example.

Referring to FIG. 1B, the first ball 81 may be in contact with a lower surface 55_L of the first pad 55. The second ball 82 may be in contact with an upper surface 65_U of the second pad 65. The first ball 81, the first pad 55, the second ball 82, and the second pad 65 may overlap each other in the third direction D3. The first ball 81 may be spaced apart from the second ball 82 in the third direction D3. The first ball 81 may be spaced apart from the wire 90 in the third direction D3.

The filling layer 40 may include an interposed part 41 between the first ball 81 and the second ball 82 and a base part 42 surrounding at least a portion of the first ball 81 and the second ball 82. In some embodiments, the first ball 81 and the second ball 82 may be on, or embedded in, the base part 42. In some embodiments, the first ball 81 and the second ball 82 may be surrounded or overlapped on at least two sides by the base part 42. The base part 42 may surround at least a portion of the first pad 55 and the second pad 65. In some embodiments, the first pad 55 and the second pad 65 may be on, or embedded in, the base part 42. In some embodiments, the first pad 55 and the second pad 65 may be surrounded or overlapped on at least two sides by the base part 42. The base part 42 may be in contact with a sidewall 55_S of the first pad 55 and a sidewall 65_S of the second pad 65. The base part 42 may be in contact with a sidewall 81_S of the first ball 81 and a sidewall 82_S of the second ball 82. The interposed part 41 may also be referred to as a first region and the base part 42 may be referred to as a second region.

The interposed part 41 may be a part overlapping the first ball 81 and the second ball 82 in the third direction D3. The interposed part 41 may be in contact with a lower surface 81_L of the first ball 81 and an upper surface 82_U of the second ball 82. The lower surface 81_L of the first ball 81 may be lower than the sidewall 81_S of the first ball 81 in the third direction D3. The upper surface 82_U of the second ball 82 may be higher than the sidewall 82_S of the second ball 82 in the third direction D3. The first ball 81 and the second ball 82 may be spaced apart by the interposed part 41 in the third direction D3. The interposed part 41 may be in contact with the wire 90. The wire 90 may be in contact with the upper surface 82_U of the second ball 82.

The filling layer 40 may include conductive particles 43. The conductive particles 43 may include, for example, at least one of gold, nickel, or lead. A density of the conductive particles 43 in the base part 42 may be lower than a density of the conductive particles 43 in the interposed part 41. A distance (e.g., average distance) between the conductive particles 43 in the base part 42 may be larger than a distance (e.g., average distance) between the conductive particles 43 in the interposed part 41. Since the distance between the conductive particles 43 in the interposed part 41 is relatively small, the conductive particles 43 may be electrically connected to each other, and the interposed part 41 may have conductivity. Since the distance between the conductive particles 43 in the base part 42 is relatively large, the conductive particles 43 may not be electrically connected to each other, and the base part 42 may have non-conductivity. In other words, the base part 42 may be an insulator.

The first ball 81 may be electrically connected to the wire 90 through the conductive particles 43 of the interposed part 41. The first ball 81 may be electrically connected to the second ball 82 through the conductive particles 43 of the interposed part 41.

In the semiconductor package 1 according to some embodiments, the first semiconductor chip 50 at an uppermost position among semiconductor chips may be electrically connected to the package substrate 20 through the interposed part 41 of the filling layer 40 and the wire 90. Accordingly, it is not necessary to form a wire loop above the first semiconductor chip 50, and thus a size of the molding layer 70 may be reduced, and a size of the semiconductor package 1 may be reduced or minimized.

Furthermore, a length of the wire 90 connecting the first semiconductor chip 50 and the package substrate 20 is reduced, and thus electrical characteristics of the semiconductor package 1 may be improved.

FIGS. 2A, 2B, 2C, and 2D are cross-sectional views for describing a method for manufacturing a semiconductor package 1 according to some embodiments.

Referring to FIG. 2A, the terminals 10 connected to the package substrate 20 may be formed. The adhesive layer 30 and the second semiconductor chip 60 may be formed on the package substrate 20.

Referring to FIG. 2B, the second ball 82 and the wire 90 connecting the second pad 65 of the second semiconductor chip 60 and the substrate pad 21 may be formed. In some embodiments, the second ball 82 and the wire 90 may be formed through a ball bonding process.

Referring to FIG. 2C, the first semiconductor chip 50 may be formed. The first ball 81 may be formed on the first pad 55 of the first semiconductor chip 50. The filling layer 40 may be formed on the first semiconductor chip 50 and the first ball 81. The filling layer 40 may include the conductive particles 43 (FIG. 1B).

Referring to FIG. 2D, the first semiconductor chip 50 and the filling layer 40 may be turned upside down. The filling layer 40 may be bonded to the second semiconductor chip 60 and the second ball 82.

In some embodiments, after the filling layer 40 is bonded to the second semiconductor chip 60 and the second ball 82, heat and pressure may be applied to the filling layer 40. For example, pressure may be applied to the interposed part 41 (FIG. 1B) of the filling layer 40 by the first ball 81 and the second ball 82. As the heat and pressure are applied to the filling layer 40, the distance between the conductive particles 43 in the interposed part 41 may become smaller than the distance between the conductive particles 43 in the base part 42 (FIG. 1B). Accordingly, the interposed part 41 of the filling layer 40 may electrically connect the first ball 81 and the second ball 82.

Referring to FIG. 1A, the molding layer 70 may be formed.

FIG. 3 is a cross-sectional view of a semiconductor package 1a according to some embodiments. The semiconductor package 1a according to FIG. 3 may be similar to the semiconductor package 1 according to FIGS. 1A and 1B except for the matters described below.

Referring to FIG. 3, a third semiconductor chip 150 and a fourth semiconductor chip 160 may be between the second semiconductor chip 60 and the package substrate 20.

The third semiconductor chip 150 may include a third substrate 151, a third insulating structure 152, third conductive structures 153, third semiconductor devices 154, and a third pad 155. The third insulating structure 152 and the third semiconductor devices 154 may be on an upper surface 151_U of the third substrate 151. The third pad 155 may be on an upper surface 152_U of the third insulating structure 152.

The fourth semiconductor chip 160 may include a fourth substrate 161, a fourth insulating structure 162, fourth conductive structures 163, fourth semiconductor devices 164, and a fourth pad 165. The fourth insulating structure 162 and the fourth semiconductor devices 164 may be on an upper surface 161_U of the fourth substrate 161. The fourth pad 165 may be on an upper surface 162_U of the fourth insulating structure 162.

A first adhesive layer 131 between the second and third semiconductor chips 60 and 150, a second adhesive layer 132 between the third and fourth semiconductor chips 150 and 160, and a third adhesive layer 133 between the fourth semiconductor chip 160 and the package substrate 20 may be provided. The first to third adhesive layers 131 to 133 may include the same polymer material.

A third ball 183 connected to the third pad 155 may be provided. A fourth ball 184 connected to the fourth pad 165 may be provided.

The package substrate 20 may include a first substrate pad 121, a second substrate pad 122, and a third substrate pad 123. A first wire 191 connecting the second ball 82 and the first substrate pad 121 may be provided. A second wire 192 connecting the third ball 183 and the second substrate pad 122 may be provided. A third wire 193 connecting the fourth ball 184 and the third substrate pad 123 may be provided.

In some embodiments, the third wire 193 may be connected to the first substrate pad 121, and the third substrate pad 123 may be omitted.

The fourth semiconductor chip 160 may be between the second and third wires 192 and 193. The second and third wires 192 and 193 may be spaced apart from each other in the first direction D1 with the fourth semiconductor chip 160 therebetween.

The third and fourth semiconductor chips 150 and 160 may be arranged between the first and second wires 191 and 192. The first and second wires 191 and 192 may be spaced apart from each other in the first direction D1 with the third and fourth semiconductor chips 150 and 160 therebetween.

The first substrate pad 121 and the second substrate pad 122 may be spaced apart from each other in the first direction D1 with the first to fourth semiconductor chips 50, 60, 150, and 160 therebetween. The third substrate pad 123 and the second substrate pad 122 may be spaced apart from each other in the first direction D1 with the first to fourth semiconductor chips 50, 60, 150, and 160 therebetween. The third substrate pad 123 may be between the first substrate pad 121 and the fourth semiconductor chip 160.

A sidewall 50_S of the first semiconductor chip 50, a sidewall 60_S of the second semiconductor chip 60, a sidewall 150_S of the third semiconductor chip 150, and a sidewall 160_S of the fourth semiconductor chip 160 may be coplanar. The sidewall 50_S of the first semiconductor chip 50, the sidewall 60_S of the second semiconductor chip 60, the sidewall 150_S of the third semiconductor chip 150, and the sidewall 160_S of the fourth semiconductor chip 160 may overlap each other in the third direction D3.

The first semiconductor chip 50, the second semiconductor chip 60, the third semiconductor chip 150, and the fourth semiconductor chip 160 may completely overlap each other in the third direction D3. The first semiconductor chip 50 may not have a portion that does not overlap the second semiconductor chip 60, the third semiconductor chip 150, and the fourth semiconductor chip 160 in the third direction D3.

FIG. 4 is a cross-sectional view of a semiconductor package 1b according to some embodiments. The semiconductor package 1b according to FIG. 4 may be similar to the semiconductor package 1 according to FIGS. 1A and 1B except for the matters described below.

Referring to FIG. 4, a third semiconductor chip 250 may be between the second semiconductor chip 60 and the package substrate 20.

The third semiconductor chip 250 may include a third substrate 251, a third insulating structure 252, third conductive structures 253, third semiconductor devices 254, and a third pad 255. The third insulating structure 252 and the third semiconductor devices 254 may be on an upper surface 251_U of the third substrate 251. The third pad 255 may be on an upper surface 252_U of the third insulating structure 252.

A first adhesive layer 231 between the second and third semiconductor chips 60 and 250 and a second adhesive layer 232 between the third semiconductor chip 250 and the package substrate 20 may be provided. The first and second adhesive layers 231 and 232 may include the same polymer material.

A third ball 283 connected to the third pad 255 may be provided.

The package substrate 20 may include a first substrate pad 221 and a second substrate pad 222. A first wire 291 connecting the second ball 82 and the first substrate pad 221 may be provided. A second wire 292 connecting the third ball 283 and the second substrate pad 222 may be provided.

The third semiconductor chip 250 may be between the first and second wires 291 and 292. The first and second wires 291 and 292 may be spaced apart from each other in the first direction D1 with the third semiconductor chip 250 therebetween.

The sidewall 50_S of the first semiconductor chip 50, the sidewall 60_S of the second semiconductor chip 60, and a sidewall 250_S of the third semiconductor chip 250 may be coplanar. The sidewall 50_S of the first semiconductor chip 50, the sidewall 60_S of the second semiconductor chip 60, and the sidewall 250_S of the third semiconductor chip 250 may overlap each other in the third direction D3.

The first semiconductor chip 50, the second semiconductor chip 60, and the third semiconductor chip 250 may completely overlap each other in the third direction D3. The first semiconductor chip 50 may not have a portion that does not overlap the second semiconductor chip 60 and the third semiconductor chip 250 in the third direction D3.

FIG. 5 is a cross-sectional view of a semiconductor package 1c according to some embodiments. The semiconductor package according 1c to FIG. 5 may be similar to the semiconductor package 1 according to FIGS. 1A and 1B except for the matters described below.

Referring to FIG. 5, a third semiconductor chip 350 and a fourth semiconductor chip 360 may be between the second semiconductor chip 60 and the package substrate 20.

The third semiconductor chip 350 may include a third substrate 351, a third insulating structure 352, third conductive structures 353, third semiconductor devices 354, and a third pad 355. The third insulating structure 352 and the third semiconductor devices 354 may be on an upper surface 351_U of the third substrate 351. The third pad 355 may be on an upper surface 352_U of the third insulating structure 352.

The fourth semiconductor chip 360 may include a fourth substrate 361, a fourth insulating structure 362, fourth conductive structures 363, fourth semiconductor devices 364, and a fourth pad 365. The fourth insulating structure 362 and the fourth semiconductor devices 364 may be on an upper surface 361_U of the fourth substrate 361. The fourth pad 365 may be on an upper surface 362_U of the fourth insulating structure 362.

A first adhesive layer 331 between the second and third semiconductor chips 60 and 350, a second adhesive layer 332 between the third and fourth semiconductor chips 350 and 360, and a third adhesive layer 333 between the fourth semiconductor chip 360 and the package substrate 20 may be provided. The first to third adhesive layers 331 to 333 may include the same polymer material.

A third ball 383 connected to the third pad 355 may be provided. A fourth ball 384 connected to the fourth pad 365 may be provided.

The package substrate 20 may include a first substrate pad 321 and a second substrate pad 322. A first wire 391 connecting the second ball 82 and the first substrate pad 321 may be provided. A second wire 392 connecting the third ball 383 and the fourth ball 384 may be provided. A third wire 393 connecting the fourth ball 384 and the second substrate pad 322 may be provided.

At least a portion of the second wire 392 may be between the third semiconductor chip 350 and the first wire 391. At least a portion of the third wire 393 may be between the fourth semiconductor chip 360 and the first wire 391.

In some embodiments, the third wire 393 may be connected to the first substrate pad 321, and the second substrate pad 322 may be omitted.

The sidewall 50_S of the first semiconductor chip 50, the sidewall 60_S of the second semiconductor chip 60, and a sidewall 350_S of the third semiconductor chip 350 may be coplanar. The sidewall 50_S of the first semiconductor chip 50, the sidewall 60_S of the second semiconductor chip 60, and the sidewall 350_S of the third semiconductor chip 350 may overlap each other in the third direction D3.

A sidewall 360_S of the fourth semiconductor chip 360 may be spaced apart from the sidewall 50_S of the first semiconductor chip 50, the sidewall 60_S of the second semiconductor chip 60, and the sidewall 350_S of the third semiconductor chip 350 in the first direction D1 (e.g., in a horizontal direction). The sidewall 360_S of the fourth semiconductor chip 360 may not overlap the sidewall 50_S of the first semiconductor chip 50, the sidewall 60_S of the second semiconductor chip 60, and the sidewall 350_S of the third semiconductor chip 350 in the third direction D3.

The fourth ball 384 and the fourth pad 365 may be arranged between the sidewall 350_S of the third semiconductor chip 350 and the sidewall 360_S of the fourth semiconductor chip 360.

The first semiconductor chip 50, the second semiconductor chip 60, and the third semiconductor chip 350 may completely overlap each other in the third direction D3. The fourth semiconductor chip 360 may partially overlap the first semiconductor chip 50, the second semiconductor chip 60, and the third semiconductor chip 350 in the third direction D3.

FIG. 6 is a cross-sectional view of a semiconductor package 1d according to some embodiments. The semiconductor package 1d according to FIG. 6 may be similar to the semiconductor package 1 according to FIGS. 1A and 1B except for the matters described below.

Referring to FIG. 6, a third semiconductor chip 450 may be between the second semiconductor chip 60 and the package substrate 20.

The third semiconductor chip 450 may include a third substrate 451, a third insulating structure 452, third conductive structures 453, third semiconductor devices 454, and a third pad 455. The third insulating structure 452 and the third semiconductor devices 454 may be on an upper surface 451_U of the third substrate 451. The third pad 455 may be on an upper surface 452_U of the third insulating structure 452.

A first adhesive layer 431 between the second and third semiconductor chips 60 and 450 and a second adhesive layer 432 between the third semiconductor chip 450 and the package substrate 20 may be provided. The first and second adhesive layers 431 and 432 may include the same polymer material.

A third ball 483 connected to the third pad 455 may be provided.

The package substrate 20 may include a first substrate pad 421 and a second substrate pad 422. A first wire 491 connecting the second ball 82 and the first substrate pad 421 may be provided. A second wire 492 connecting the third ball 483 and the second substrate pad 422 may be provided.

In some embodiments, the second wire 492 may be connected to the first substrate pad 421, and the second substrate pad 422 may be omitted.

The sidewall 50_S of the first semiconductor chip 50 and the sidewall 60_S of the second semiconductor chip 60 may be coplanar. The sidewall 50_S of the first semiconductor chip 50 and the sidewall 60_S of the second semiconductor chip 60 may overlap each other in the third direction D3.

A sidewall 450_S of the third semiconductor chip 450 may be spaced apart from the sidewall 50_S of the first semiconductor chip 50 and the sidewall 60_S of the second semiconductor chip 60 in the first direction D1 (e.g., in a horizontal direction). The sidewall 450_S of the third semiconductor chip 450 may not overlap the sidewall 50_S of the first semiconductor chip 50 and the sidewall 60_S of the second semiconductor chip 60 in the third direction D3.

The third ball 483 and the third pad 455 may be arranged between the sidewall 450_S of the third semiconductor chip 450 and the sidewall 60_S of the second semiconductor chip 60.

The first semiconductor chip 50 and the second semiconductor chip 60 may completely overlap each other in the third direction D3. The third semiconductor chip 450 may partially overlap the first semiconductor chip 50 and the second semiconductor chip 60 in the third direction D3.

FIG. 7 is a cross-sectional view of a semiconductor package 1e according to some embodiments. The semiconductor package 1e according to FIG. 7 may be similar to the semiconductor package 1 according to FIGS. 1A and 1B except for the matters described below.

Referring to FIG. 7, the first semiconductor chip 550 may include a first substrate 551, a first insulating structure 552, first conductive structures 553, first semiconductor devices 554, a first pad 555, and a through-via 556. The first insulating structure 552 and the first semiconductor devices 554 may be on an upper surface 551_U of the first substrate 551. The first pad 555 may be on a lower surface 551_L of the first substrate 551. The first substrate 551 may be between the first pad 555 and the first semiconductor device 554. The first through-via 556 may penetrate the first substrate 551 in the third direction D3 and connect the first conductive structure 553 and the first pad 555.

FIG. 8 is a cross-sectional view of a semiconductor package 1f according to some embodiments. The semiconductor package 1f according to FIG. 8 may be similar to the semiconductor package 1 according to FIGS. 1A and 1B except for the matters described below.

Referring to FIG. 8, the second semiconductor chip 660 may include a second substrate 661, a second insulating structure 662, second conductive structures 663, second semiconductor devices 664, a second pad 665, and a through-via 666. The second insulating structure 662 and the second semiconductor devices 664 may be on a lower surface 661_L of the second substrate 661. The second pad 665 may be on an upper surface 661_U of the second substrate 661. The second substrate 661 may be between the second pad 665 and the second semiconductor device 664. The through-via 666 may penetrate the second substrate 661 in the third direction D3 and connect the second conductive structure 663 and the second pad 665.

FIG. 9 is a cross-sectional view of a semiconductor package 1g according to some embodiments. The semiconductor package 1g according to FIG. 9 may be similar to the semiconductor package 1 according to FIGS. 1A and 1B except for the matters described below.

Referring to FIG. 9, a first semiconductor chip 750 may include a first substrate 751, a first insulating structure 752, first conductive structures 753, first semiconductor devices 754, a first pad 755, and a first through-via 756. The first insulating structure 752 and the first semiconductor devices 754 may be on an upper surface 751_U of the first substrate 751. The first pad 755 may be on a lower surface 751_L of the first substrate 751. The first substrate 751 may be between the first pad 755 and the first semiconductor device 754. The first through-via 756 may penetrate the first substrate 751 in the third direction D3 and connect the first conductive structure 753 and the first pad 755.

A second semiconductor chip 760 may include a second substrate 761, a second insulating structure 762, second conductive structures 763, second semiconductor devices 764, a second pad 765, and a second through-via 766. The second insulating structure 762 and the second semiconductor devices 764 may be on a lower surface 761_L of the second substrate 761. The second pad 765 may be on an upper surface 761_U of the second substrate 761. The second substrate 761 may be between the second pad 765 and the second semiconductor device 764. The second through-via 766 may penetrate the second substrate 761 in the third direction D3 and connect the second conductive structure 763 and the second pad 765.

FIG. 10 is an enlarged view of a semiconductor package 1h according to some embodiments. The semiconductor package 1h according to FIG. 10 may be similar to the semiconductor package 1 according to FIGS. 1A and 1B except for the matters described below.

Referring to FIG. 10, a filling layer 840 may include an interposed part 841 and a base part 842. The filling layer 840 may not include conductive particles. The filling layer 840 may include a polymer material. For example, the filling layer 840 may include a non-conductive film (NCF).

A first ball 881 may be in contact with a wire 890. The first ball 881 may be electrically connected to the second ball 882 through the wire 890. In some embodiments, the first ball 881 may be in contact with the second ball 882.

The semiconductor package according to some embodiments of the inventive concept does not require formation of a wire loop at an upper portion of the semiconductor package, and thus the size of the semiconductor package may be reduced or minimized.

The semiconductor package according to some embodiments of the inventive concept may have a relatively short wire electrically connected to an uppermost semiconductor chip, and thus the electrical characteristics of the semiconductor package may be improved.

Although some embodiments of the present invention have been described, it is understood that the present invention should not be limited to these embodiments. Various changes and modifications can be made by one of ordinary skill in the art within the spirit and scope of the present invention as hereinafter claimed.

What is claimed is:

1. A semiconductor package comprising:
a first semiconductor chip including a first pad;
a second semiconductor chip including a second pad;
a package substrate including a substrate pad;
a filling layer between the first semiconductor chip and the second semiconductor chip;
a first ball connected to the first pad;
a second ball connected to the second pad; and
a wire connected to the second ball and the substrate pad,
wherein the filling layer surrounds at least a portion of the first ball and the second ball, and
wherein the first ball overlaps the second ball and is spaced apart from the wire and the second ball.

2. The semiconductor package of claim 1, wherein the filling layer includes an interposed part between the first ball and the second ball, and a base part surrounding at least a portion of the first ball and the second ball.

3. The semiconductor package of claim 2, wherein the filling layer includes conductive particles, and
wherein a density of the conductive particles in the base part is lower than a density of the conductive particles in the interposed part.

4. The semiconductor package of claim 2, wherein the first ball is electrically connected to the wire through the interposed part.

5. The semiconductor package of claim 1, wherein the first semiconductor chip includes:
a first substrate; and
a first semiconductor device on a lower surface of the first substrate and electrically connected to the first pad, and
wherein the second semiconductor chip includes:
a second substrate; and
a second semiconductor device on an upper surface of the second substrate and electrically connected to the second pad.

6. The semiconductor package of claim 1, further comprising:
an adhesive layer between the second semiconductor chip and the package substrate, and
wherein the adhesive layer includes a material different from the filling layer.

7. A semiconductor package comprising:
a first semiconductor chip including a first pad;
a second semiconductor chip including a second pad;
a package substrate including a substrate pad;
a filling layer between the first semiconductor chip and the second semiconductor chip;
a first ball connected to the first pad;
a second ball connected to the second pad; and
a first wire connected to the second ball and the substrate pad,
wherein the filling layer includes a base part surrounding at least a portion of the first ball and the second ball and an interposed part between the first ball and the second ball.

8. The semiconductor package of claim 7, wherein the interposed part is in contact with the first wire.

9. The semiconductor package of claim 7, further comprising:
a third semiconductor chip between the second semiconductor chip and the package substrate and including a third pad;
a third ball connected to the third pad; and
a second wire connected to the third ball.

10. The semiconductor package of claim 9, wherein a sidewall of the first semiconductor chip and a sidewall of the second semiconductor chip are coplanar with each other, and
wherein a sidewall of the third semiconductor chip is spaced apart from the sidewall of the first semiconductor chip and the sidewall of the second semiconductor chip in a horizontal direction.

11. The semiconductor package of claim 10, wherein at least a portion of the second wire is between the first wire and the third semiconductor chip.

12. The semiconductor package of claim 11, further comprising:
a fourth semiconductor chip between the second semiconductor chip and the third semiconductor chip and including a fourth pad;
a fourth ball connected to the fourth pad; and
a third wire connected to the fourth ball and the third ball.

13. The semiconductor package of claim 9, wherein a sidewall of the first semiconductor chip, a sidewall of the second semiconductor chip, and a sidewall of the third semiconductor chip are coplanar with each other, and
wherein the third semiconductor chip is between the first wire and the second wire.

14. The semiconductor package of claim 7, wherein the first semiconductor chip includes:
a substrate;
a semiconductor device on an upper surface of the substrate;
a conductive structure connected to the semiconductor device; and
a through-via connecting the conductive structure and the first pad, and
wherein the through-via penetrates the substrate.

15. The semiconductor package of claim 7, wherein the first semiconductor chip includes:
a first substrate;
a first semiconductor device on a lower surface of the first substrate;
a first insulating structure surrounding at least a portion of the first semiconductor device; and
first conductive structures in the first insulating structure and configured to electrically connect the first semiconductor device and the first pad,
wherein the second semiconductor chip includes:
a second substrate;
a second semiconductor device on a lower surface of the second substrate;
a second insulating structure surrounding at least a portion of the second semiconductor device; and
second conductive structures in the second insulating structure and electrically connecting the second semiconductor device and the second pad,
wherein the first and second insulating structures are arranged between the first and second substrates, and
wherein the filling layer is between the first and second insulating structures.

16. A semiconductor package comprising:
a first semiconductor chip;
a second semiconductor chip overlapping the first semiconductor chip;
a package substrate on the second semiconductor chip and including a substrate pad;
a first ball connected to the first semiconductor chip;
a second ball connected to the second semiconductor chip and spaced apart from the first ball;
a wire connected to the second ball and the substrate pad and spaced apart from the first ball;
a filling layer between the first semiconductor chip and the second semiconductor chip and surrounding at least a portion of the first ball and the second ball;
an adhesive layer between the second semiconductor chip and the package substrate; and
a molding layer surrounding at least a portion of the first semiconductor chip, the second semiconductor chip, and the wire,
wherein the first semiconductor chip includes:
a first pad connected to the first ball;
a first substrate;
a first semiconductor device on a lower surface of the first substrate;
a first insulating structure surrounding at least a portion of the first semiconductor device; and
first conductive structures in the first insulating structure and electrically connecting the first semiconductor device and the first pad,
wherein the second semiconductor chip includes:
a second pad connected to the second ball;
a second substrate;
a second semiconductor device on an upper surface of the second substrate;
a second insulating structure surrounding at least a portion of the second semiconductor device; and
second conductive structures in the second insulating structure and configured to electrically connect the second semiconductor device and the second pad, and
wherein the filling layer electrically connects the first ball and the wire.

17. The semiconductor package of claim 16, wherein the filling layer includes an interposed part between the first ball and the second ball.

18. The semiconductor package of claim 17, wherein the interposed part includes conductive particles configured to electrically connect the first ball and the second ball.

19. The semiconductor package of claim 16, wherein the first pad, the second pad, the first ball, and the second ball overlap each other.

20. The semiconductor package of claim 16, wherein the wire is in contact with an upper surface of the second ball.
